(19) United States
(12) Patent Application Publication
(10) Pub. No.: US 2013/0213465 A1
(43) Pub. Date: Aug. 22, 2013

(54) Oxide Thin Film Substrate, Method Of Manufacturing The Same, And Photovoltaic Cell And Organic Light-Emitting Device Including The Same

(71) Applicant: Samsung Corning Precision Materials Co., Ltd., (US)

(72) Inventors: SooHo Park, ChungCheongNam-Do (KR); SeoHyun Kim, ChungCheongNam-Do (KR); JeongWoo Park, ChungCheongNam-Do (KR); Junehyoung Park, ChungCheongNam-Do (KR); Taejung Park, ChungCheongNam-Do (KR); Ilhee Baek, ChungCheongNam-Do (KR); YoungZo Yoo, ChungCheongNam-Do (KR); GunSang Yoon, ChungCheongNam-Do (KR); Hyunhee Lee, ChungCheongNam-Do (KR); Eun-Ho Choi, ChungCheongNam-Do (KR)

(73) Assignee: SAMSUNG CORNING PRECISION MATERIALS CO., LTD., Gyeongsangbuk-do (KR)

(21) Appl. No.: 13/771,607

(22) Filed: Feb. 20, 2013

(30) Foreign Application Priority Data
Feb. 21, 2012 (KR) 10-2012-0017479

(51) Int. Cl. H01L 31/0236; H01L 31/18; H01L 31/0224; H01L 51/00

(52) U.S. Cl. CPC H01L 31/02366; H01L 51/0001; H01L 31/1884; H01L 31/022466; H01L 51/0096
USPC 136/256; 427/66; 427/126.3; 428/142

(57) ABSTRACT

An oxide thin film substrate which has a high haze value, a method of manufacturing the same, and a photovoltaic cell and organic light-emitting device including the same. The oxide thin film substrate includes a base substrate having a first texture on the surface thereof and a transparent oxide thin film formed on the base substrate. The transparent oxide thin film has a second texture on the surface thereof.

### CROSS REFERENCE TO RELATED APPLICATION

The present application claims priority from Korean Patent Application Number 10-2012-0017479 filed on Feb. 21, 2012, the entire contents of which application are incorporated herein for all purposes by this reference.

### BACKGROUND OF THE INVENTION

1. Field of the Invention

The present invention relates to an oxide thin film substrate, a method of manufacturing the same, and a photovoltaic cell and organic light-emitting device including the same, and more particularly, to an oxide thin film substrate which has a high haze value, a method of manufacturing the same, and a photovoltaic cell and organic light-emitting device including the same.

2. Description of Related Art

In general, a transparent oxide thin film is used for a transparent electrode of a photovoltaic cell or a light extraction layer that is intended to increase light extraction efficiency depending on its conductivity. Here, a texture is formed on the surface of the transparent electrode of the photovoltaic cell and the light extraction layer of the organic light-emitting device in order to increase optical efficiency.

Zinc oxide (ZnO) is a common element for an oxide thin film which forms a transparent electrode of a photovoltaic cell and a light extraction layer of an organic light-emitting device. ZnO is formed as a thin film coating on a glass substrate via atmospheric pressure chemical vapor deposition (APCVD), which is suitable for mass production, for example, due to its rapid sputtering or coating rate and high productivity, thereby forming a transparent electrode for a photovoltaic cell or a light extraction layer of an organic light-emitting device.

However, the APCVD has a problem in that neither stability nor processing for an organic precursor or the like has been established. During the sputtering process, a glass substrate is coated with a thick oxide film, which is in turn imparted with a surface texture via wet etching. However, this process is generally divided into two steps, and has limited ability for mass production.

In the meantime, an oxide thin film which is used for a photovoltaic cell or an organic light-emitting device exhibits better optical efficiency when its haze value is higher. The haze value is determined by the texture that is formed on the surface of the oxide thin film. However, the approach of the related art that uses simple etching on the oxide thin film has limited ability to increase the haze value by controlling the shape of the texture. In addition, when the oxide thin film is used for a transparent electrode of a photovoltaic cell, there is a trade-off between the optical characteristics and the electrical characteristics of the electrode. Due to this problem, control over the shape of the texture has many difficulties. Specifically, when the oxide thin film is used for a transparent electrode of the photovoltaic cell, increasing the haze value of the oxide thin film leads to an increase in the sheet resistance (Ω/□) of the film, thereby degrading the electrical characteristics of the oxide thin film, which is problematic.

The information disclosed in the Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide an oxide thin film substrate which has a high haze value, a method of manufacturing the same, and a photovoltaic cell and organic light-emitting device including the same.

In an aspect of the present invention, provided is an oxide thin film substrate that includes a base substrate having a first texture on the surface thereof; and a transparent oxide thin film formed on the base substrate, the transparent oxide thin film having a second texture on the surface thereof.

In an exemplary embodiment, the first texture may include a plurality of first projections formed on the surface of the base substrate and a plurality of second projections, at least one second projection from among the plurality of second projections being formed on the surface of each of the plurality of first projections.

The surface roughness (RMS) of the base substrate may range from 0.1 μm to 20 μm.

The width and a height of the second projection may range from 0.1 μm to 1 μm.

The second texture may include a plurality of third projections formed on the surface of the transparent oxide thin film and a plurality of fourth projections formed on the entire surface of the transparent oxide thin film, including on the surfaces of the plurality of third projections.

Each of the plurality of third projections may be formed at a position corresponding to the second projection.

The width of the third projections may range from 0.1 μm to 5 μm, the distance between adjacent third projections from among the plurality of third projections may range from 0 μm to 10 μm, and the height of the third projections may range from 0.1 μm to 5 μm.

The width of the fourth projections may range from 0.01 μm to 0.4 μm, the distance between adjacent fourth projections from among the plurality of fourth projections may range from 0.01 μm to 0.4 μm, and the height of the fourth projections may range from 0.01 μm to 0.5 μm.

In addition, the haze value of the oxide thin film may range from 75% to 86%.

In addition, the sheet resistance of the transparent oxide thin film may range from 49Ω/□ to 75 Ω/□.

In another aspect of the present invention, provided is a method of manufacturing an oxide thin film substrate. The method includes the following steps of: forming a first texture on the surface of a base substrate by etching the surface of the base substrate; and coating the surface of the base substrate on which the first texture is formed with a transparent oxide thin film, thereby forming a second texture on the surface of the transparent oxide thin film.

In an exemplary embodiment, the step of forming the first texture on the surface of the base substrate may include etching the surface of the substrate via sandblaster processing.

In addition, the step of coating the surface of the base substrate with the transparent oxide thin film may include coating the base substrate with the transparent oxide thin film via atmospheric pressure chemical vapor deposition (APCVD).

In a further aspect of the present invention, provided is a photovoltaic cell that includes the above-described oxide thin film substrate as a transparent electrode substrate.

In further another aspect of the present invention, provided is an organic light-emitting device that includes the above-described oxide thin film substrate as a light extraction substrate.

According to embodiments of the invention, since the texture is naturally formed on the surface of an oxide thin film due to the texture on a base substrate, it is not required to etch the surface of the oxide thin film to form a texture thereon. It is therefore possible to simplify the process and control the shape of the texture on the surface of the oxide thin film, thereby increasing the haze value of the oxide thin film.

In addition, according to embodiments of the invention, it is possible to calculate the optimum texturing conditions to increase the haze value while minimizing any decreases in the electrical characteristics of the oxide thin film, thereby controlling the shape of the texture. This consequently overcomes the problem of the trade-off between the electrical characteristics and haze value of the oxide thin film.

Furthermore, according to embodiments of the invention, it is possible to improve the optical characteristics of a transparent electrode of a photovoltaic cell and a light extraction layer of an organic light-emitting device by applying the oxide thin film having a high haze value thereto.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a cross-sectional view showing an oxide thin film substrate according to an embodiment of the invention (in which it is cut along the direction of thickness of a base substrate);

FIG. 2 is a conceptual view schematically showing the process of etching the surface of a base substrate in a method of manufacturing an oxide thin film substrate according to an embodiment of the invention;

FIG. 3 is scanning electron microscopy (SEM) pictures showing the surface of a glass substrate after it has been coated with zinc oxide;

FIG. 4 is SEM pictures showing the surface of a glass substrate after it has been sandblast-etched;

FIG. 5 is SEM pictures showing the surface of the glass substrate shown in FIG. 4 after it has been coated with zinc oxide;

FIG. 6 is SEM pictures showing the cross-section of the glass substrate shown in FIG. 5; and

FIG. 7 is a graph showing transmittances of an oxide thin film substrate according to an embodiment of the invention which are integrated and diffracted depending on the steps thereof.

### DETAILED DESCRIPTION OF THE INVENTION

Reference will now be made in detail to an oxide thin film substrate, a method of manufacturing the same, and a photovoltaic cell and organic light-emitting device including the same according to the present invention, embodiments of which are illustrated in the accompanying drawings and described below.

Throughout this document, reference should be made to the drawings, in which the same reference numerals and signs are used throughout the different drawings to designate the same or similar components. In the following description of the present invention, detailed descriptions of known functions and components incorporated herein will be omitted when they may make the subject matter of the present invention unclear.

As shown in FIG. 1, an oxide thin film substrate according to an embodiment of the invention includes a base substrate 1 and a transparent oxide thin film 2.

The base substrate 1 is a base substrate on which the transparent oxide thin film 2 is formed, and can be implemented as a glass substrate having a haze value of 0.8%. A first texture is formed on the surface of the base substrate 1. The first texture is a base pattern with which a second texture which will be described later is induced to naturally form on the surface of the transparent oxide thin film 2. The first texture can be formed by etching the surface of the base substrate 1 via sandblasting, which will be described in more detail later in the manufacturing method.

When the first texture is formed on the surface of the base substrate 1, the haze value of the base substrate 1 increases to about 62.6%, and the surface roughness of the base substrate 1 is in the range from 0.1 μm to 20 μm. The first texture can include first projections 3 and second projections 4.

The first projections 3 can consist of a plurality of projections which are continuously or discontinuously formed on the surface of the base substrate 1 by etching the surface of the base substrate 1. As shown in the figure, one or two second projections 4 can be formed at irregular positions on the surface of the first projection 3. Here, the width Wsr and the height Hsr of each second projection 4 can be determined in the range from 0.01 μm to 1 μm. The width indicates the length that is measured on the surface of the first projection that serves as a reference plane, and the height indicates the length that is measured from the surface of the first projection that serves as the reference plane.

The transparent oxide thin film 2 is formed on the surface of the base substrate 1, i.e. on the surface of the first texture formed on the surface of the base substrate 1. When the transparent oxide thin film 2 is used for a light extraction layer of an organic light-emitting device, it can be made of a mixture which includes at least one selected from a substance group including ZnO, TiO₂, SnO₂, SrTiO₃, VO₂, V₂O₃ and SrRuO₃. When the transparent oxide thin film 2 is used for a transparent electrode of a photovoltaic cell, it can be made of, for example, ZnO that has excellent conductivity. The second texture is formed on the surface of the transparent oxide thin film 2 according to an embodiment of the invention. Here, the transparent oxide thin film 2 can be formed as a coating on the surface of the base via atmospheric pressure chemical vapor deposition (APCVD). Since the first texture is formed on the surface of the base substrate 1 in advance, in the process in which the first texture is covered with a material that is to form the transparent oxide thin film 2 during the coating, the second texture is naturally formed on the surface of the transparent oxide thin film 2 due to the shape of the first texture.

In this fashion, the haze value of the transparent oxide thin film 2 is further increased within the range from 75% to 86% due to the second texture formed on the surface. In addition, the sheet resistance of the transparent oxide thin film 2 exhibits a range from 49Ω/□ to 75Ω/□. Considering that the sheet resistance of ZnO which does not have a texture on the surface thereof is 45Ω/□, an increase in the sheet resistance by the second texture is not significant compared to the haze value that is increased due to the second texture. It is therefore possible to minimize degradation in the electrical characteristics of the transparent oxide thin film 2. This phenomenon is caused by the shape of the second texture, which will be described in more detail later.

The second texture includes third projections 5 and fourth projections 6. Here, the third projections 5 are induced by the shape of the first texture of the glass base substrate 1 while the fourth projections 6 are formed separately from the third projections 5, specifically, by APCVD that is used when forming the transparent oxide thin film 2.

A plurality of the third projections 5 can be formed on the surface of the transparent oxide thin film 2, specifically, at positions corresponding to the second projections 4 of the first texture. It is preferred that the width Da of each third projection 5 range from 0.1 μm to 5 μm, that the distance Wa between the adjacent third projections 5 range from 0 μm to 10 μm, and that the height of each third projection 5 range from 0.1 μm to 5 μm. Here, the width and distance indicate lengths that are measured on the surface of the second texture that serves as a reference plane, and the height indicates a length that is measured from the surface of the second texture that serves as the reference plane.

Table 1 below presents variations in the haze value and the sheet resistance depending on the size of the third projections 5. As presented in Table 1, as the size of the third projections 5 increases, the surface becomes rougher, thereby increasing the haze value. However, when variations in the haze value are examined, the haze value greatly increases up to 1 μm but exhibits an almost saturated increase thereafter. In addition, the sheet resistance increases as the size of the third projections 5 increases. However, when variations in the sheet resistance are examined, the sheet resistance increases by a small amount, up to 1 μm, but significantly increases from 5 μm. Therefore, in order to satisfy the sheet resistance, that is, minimize the increase in the sheet resistance while increasing the haze value, it is preferred that the width Da and the height Ha of the third projections 5 range from 0.1 μm to 5 μm. Here, the size of the third projections 5 can be adjusted by controlling etching conditions on the surface of the base substrate 1.

TABLE 1

| Mean size (width and height) | | Sheet resistance |
|---|---|---|
| of 3^{rd} projections (μm) | Haze (%) | (Ω/□) |
| 0 (Substrate | 62.6 | — |
| having texture) | | |
| 0.1 | 75 | 49 |
| 0.5 | 81 | 53 |
| 1 | 84 | 54.6 |
| 5 | 86 | 75 |
| 10 | 87 | 99 |

The fourth projections 6 are continuously formed on the entire surface of the transparent oxide thin film 2. That is, the fourth projections 6 are continuously formed on the surface of the plurality of third projections 5 and the entire area of the surface of the transparent oxide thin film 2 on which the third projections 5 are not formed. Here, the distance Wp between the adjacent fourth projections 6 can range from 0.01 μm to 0.4 μm, the width Dp of each fourth projection 6 can range from 0.01 μm to 0.4 μm, and the height Hp of each fourth projection 6 can range from 0.01 μm to 0.5 μm. The width and distance indicate lengths that are measured on the surface of the second texture that serves as a reference plane, and the height indicates the length that is measured from the surface of the second texture that serves as the reference plane. The fourth projections 6 serve to more greatly increase the light scattering effect that is realized by the third projections 5.

As described above, in the oxide thin film substrate according to an embodiment of the invention, it is possible to control the sheet resistance as desired while increasing the haze value due to the texture that is induced from the first texture formed on the base substrate 1, i.e. the second texture formed on the surface of the transparent oxide thin film 2. It is therefore possible to improve the optical characteristics of devices to which the oxide thin film substrate according to an embodiment of the invention is applied.

In an example, the oxide thin film substrate according to an embodiment of the invention can be used for a transparent electrode of a photovoltaic cell. The photovoltaic cell is a photovoltaic element that directly converts light energy, for example, solar energy into electricity.

Although not specifically illustrated, the photovoltaic cell can have a laminated structure including a cover glass, a first buffer material, a cell, a second buffer material and a rear sheet which are stacked on one another. The cover glass serves to protect the cell from the external environment, such as moisture, dust, damage or the like. The buffer materials are layers which protect the cell from the external environment, such as moisture, and encapsulate the cell by bonding it to the cover glass. The buffer materials can be made of ethylene vinyl acetate (EVA). The cell is implemented as, for example, a power generating device which generates a voltage and current from solar light. In an example, the cell can include a transparent conductive oxide electrode, a light-absorbing layer, a rear electrode layer and an insulating film. The light-absorbing layer can be made of a semiconductor compound, such as single crystal or polycrystal silicon, copper indium gallium Selenide (CIGS) or cadmium telluride (CdTe), a dye-sensitized material in which photo-sensitive dye molecules, electrons of which are excited by absorbed visible light, are adsorbed by the surface of nano-particles of a porous film, amorphous silicon, or the like. The transparent oxide thin film 2 of the oxide thin film substrate according to an embodiment of the invention can be used for the transparent conductive oxide electrode of the cell. The base substrate 1 serves as a support substrate which supports the transparent conductive oxide electrode.

The oxide thin film substrate according to an embodiment of the invention can also be used for a light extraction layer of an organic light-emitting device. Specifically, the base substrate 1 of the oxide thin film substrate forms any one of encapsulation substrates of an organic light-emitting device which are arranged to face each other, and the transparent oxide thin film 2 formed on the base substrate 1 serves as a light extraction layer.

Briefly describing, the organic light-emitting device includes a laminated structure in which an anode, an organic light-emitting layer and a cathode are disposed between a pair of opposing encapsulation substrates. The anode can be made of a metal or oxide, such as Au, In, Sn or ITO, which has a large work function in order to facilitate hole injection. The cathode can be made of a metal thin film of Al, Al:Li or Mg:Ag which has a small work function in order to facilitate electron injection. In the case of a top emission structure, the cathode can be implemented as a multilayer structure which includes a translucent electrode of a metal thin film that is made of, for example, Al, Al:Li or Mg:Ag and a transparent electrode of an oxide thin film that is made of, for example, indium tin oxide (ITO) in order to facilitate the passage of light that has been generated from an organic light-emitting layer. In addition, the organic light-emitting layer includes a hole injection layer, a hole carrier layer, a light-emitting layer, an electron carrier layer and an electron injection layer which are sequentially stacked on the anode. According to this structure, when a forward voltage is applied between the anode and cathode, electrons migrate from the cathode to the light-emitting layer through the electron injection layer and the electron carrier layer, whereas holes migrate from the anode to the light-emitting layer through the hole injection layer and the hole carrier layer. The electrons and holes that have migrated into the light-emitting layer recombine in the light-emitting layer, thereby generating excitons, which in turn emit light while transiting from an excited state into the ground state. At this time, the brightness of light that is generated is proportional to the intensity of a current that flows between the anode and the cathode.

When the thin oxide thin film substrate according to an embodiment of the invention which exhibits a high haze value as described above is used for a transparent electrode of a thin film-type photovoltaic cell or a light extraction layer of an organic light-emitting device, it is possible to further improve the optical characteristics of these devices.

A description will be given below of a method of manufacturing the oxide thin film substrate according to an embodiment of the invention.

The method of manufacturing the oxide thin film substrate according to an embodiment of the invention includes, first, the step for forming a first texture on the surface of a base substrate 1 by etching. The etching of the surface of the base substrate 1 can be carried out via sandblasting.

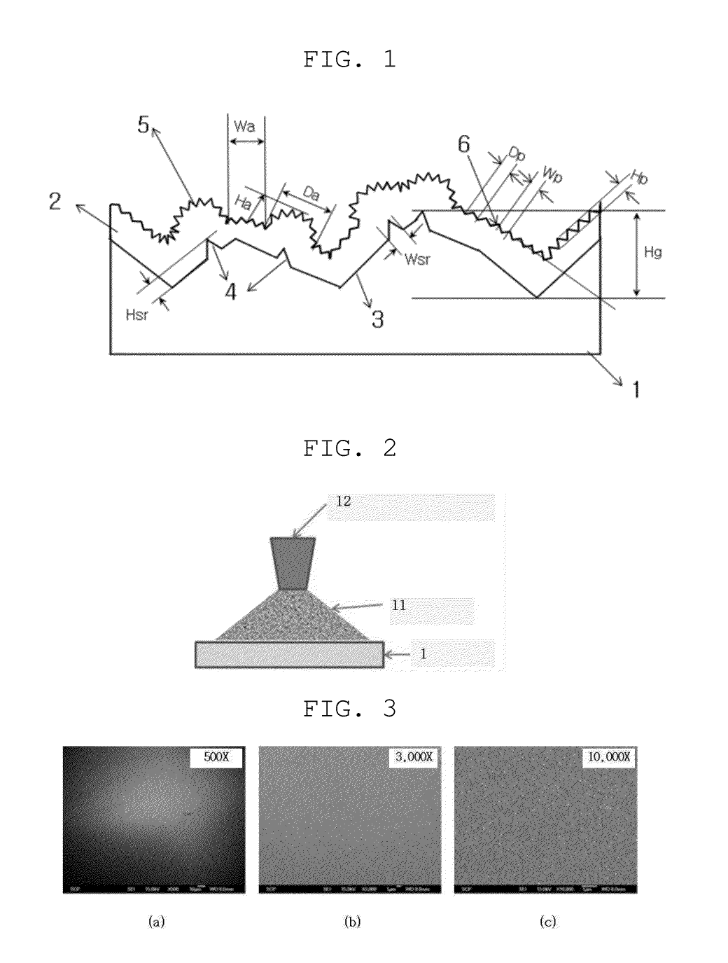

As shown in FIG. 2, sandblasting is carried out by ejecting abrasive 11 to the surface of the base substrate 1 through a nozzle 12. During sandblasting, the degree of etching is determined by pneumatic pressure that is applied to the nozzle 12, and influences the shape of the first texture that is to be formed. According to this embodiment of the invention, the abrasive 11 is ejected to the surface of the base substrate 1 by controlling the pneumatic pressure within the range from 0.5 atm to 20 atm, preferably, from 1 atm to 10 atm during sandblasting. In addition, during sandblasting, any one element selected from among alumina, zirconia, glass and plastic can be used as the abrasive 11. Preferably, alumina, zirconia or glass can be used for the abrasive 11. In order to obtain an intended shape of the first texture, the grain diameter of the abrasive 11 that is to be used can be controlled within the range from 0.5 μm to 1000 μm, preferably, from 1 μm to 530 μm.

Furthermore, during sandblasting in which the abrasive 11 as described above is ejected, the distance between the nozzle 12 which ejects the abrasive 11 and the base substrate 1 acts as a process variable, which in turn influences the quality or degree of etching. Consequently, in an embodiment of the invention, it is possible to control the distance between the nozzle 12 and the base substrate 1 within the range from 0.5 cm to 30 cm, preferably, from 2 cm to 10 cm.

One of key process conditions during sandblasting is the angle at which the abrasive 11 is ejected through the nozzle 12. According to an embodiment of the invention, the angle at which the abrasive 11 is ejected can be controlled to be 60° or less, preferably, 45° or less with respect to vertical ejection.

In this fashion, it is possible to produce the first texture having an intended shape, i.e. the first texture including first projections and second projections, by controlling the process conditions of sandblasting, specifically, the pneumatic pressure, the type of the abrasive 11, the particle diameter of the abrasive 11, the distance between the nozzle 12 and the base substrate 1 and the angle at which the abrasive 11 is ejected. The shape control over the first texture makes it possible to control the shape of the second texture which is induced by the first texture to an intended level.

FIG. 4 is scanning electron microscopy (SEM) pictures showing the surface of a base substrate 1 that has been sandblast-etched, the SEM pictures taken by varying the magnifying power of the microscope. It can be visually confirmed that a first texture is formed on the surface of the base substrate 1 due to etching.

Afterwards, the surface of the base substrate 1 on which the first texture is formed by sandblasting is coated with a transparent oxide thin film 2, thereby forming a second texture on the surface of the transparent oxide thin film 2. The transparent oxide thin film 2 can be formed by any one process selected from among, but not limited to, atmospheric pressure chemical vapor deposition (APCVD), low pressure chemical vapor deposition (LPCVD), sputtering and molecular beam epitaxy. When the transparent oxide thin film 2 is formed by the APCVD from among these processes, concaves and convexes are naturally formed in the surface of the transparent oxide thin film 2, thereby forming fourth projections 6. In addition, concaves and convexes are also induced by the first texture of the base substrate 1, thereby forming third projections 5. In other words, when the transparent oxide thin film 2 is applied as a coating on the base substrate 1 having the first texture, the second texture including the third projections 5 and the fourth projections 6 is formed.

In the APCVD, first, the base substrate 1 having the first texture on the surface thereof is loaded into a process chamber (not shown) and is then heated at a predetermined temperature. Afterwards, a precursor gas and an oxidizer gas are blowing into the process chamber (not shown) for the purpose of an APCVD reaction. In order to prevent the precursor gas and the oxidizer gas from mixing before entering the process chamber (not shown), it is preferred that the gases be controlled so that they are supplied along different paths. The precursor gas and the oxidizer gas can be preheated before being blown in order to promote a chemical reaction. Here, the precursor gas can be blown into the process chamber (not shown) on a carrier gas which is implemented as an inert gas, such as nitrogen, helium and argon.

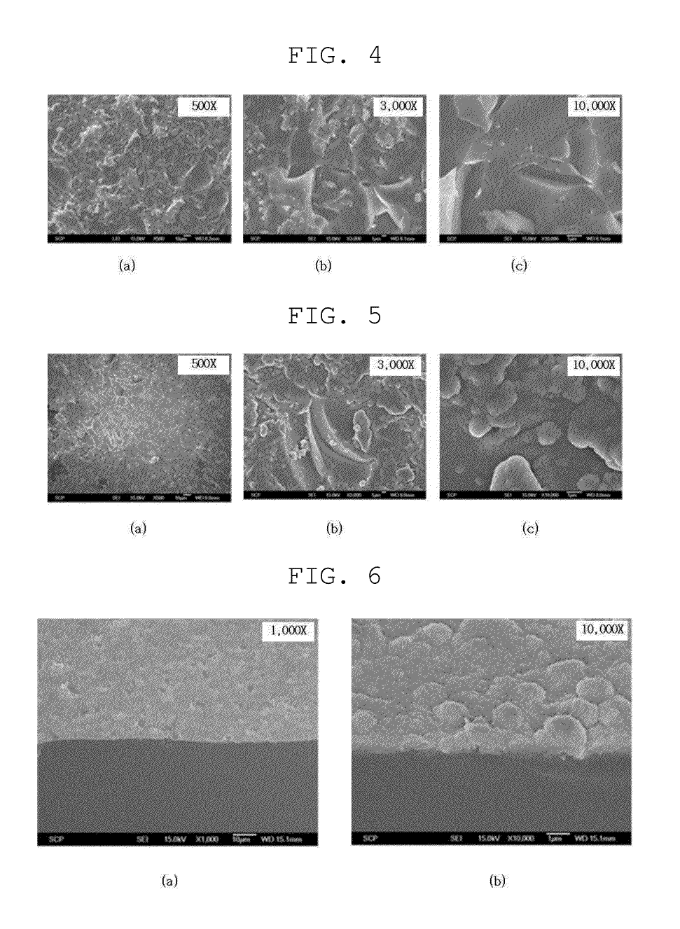

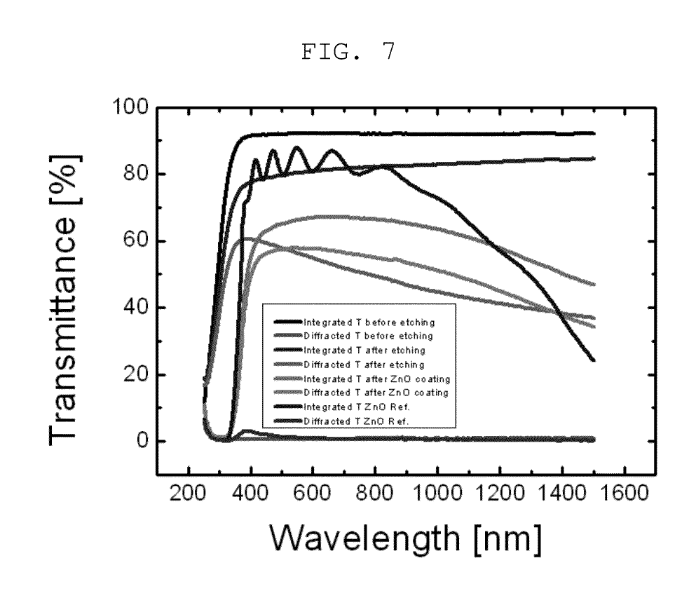

FIG. 5 and FIG. 6 are SEM pictures showing the surface and cross-section of the base substrate 1 that has been sandblast-etched, the SEM pictures taken by varying the magnifying power of the microscope after the base substrate 1 has been coated with the transparent oxide thin film 2 of ZnO. It can be visually confirmed that a second texture is formed on the surface of the transparent oxide thin film 2. When compared to the SEM pictures of FIG. 3 that were taken after the glass substrate without a texture has been coated with ZnO, the existence and shape of the texture are clearly discriminated.

In addition, FIG. 7 and Table 2 below present transmittances and haze values depending on steps when a glass substrate which has not been sandblast-etched and a glass substrate which has been sandblast-etched are coated with an oxide thin film of ZnO. Referring to FIG. 7 and Table 2, it can be confirmed that the transmittances decreased more or less after the substrate has been etched or coated with ZnO. However, the haze values in the wavelength range from 400 nm to 1100 nm greatly increased from less than 1% before etching to 62.6% after etching and to 84% after ZnO coating. This is as 84 times great as a reference haze value of 1% that is obtained when a glass substrate which has not been etched is coated with ZnO.

TABLE 2

| Sample | Glass substrate | Glass substrate | Etching/ZnO | ZnO |
|---|---|---|---|---|
| condition | before etching | after etching | coating | reference |
| Haze | 0.8% | 62.6% | 84.0% | 1.0% |

In addition, Table 3 below presents variation in sheet resistance before and after etching. As presented in Table 3, when the glass substrate which has not been etched is coated with ZnO, the sheet resistance of a reference is 45Ω/□. In contrast, a sample in which the glass substrate is coated with ZnO after being etched has a sheet resistance of about 54.6Ω/□. It can be appreciated that, when the glass substrate is etched in order to increase the haze value, an increase in the sheet resistance is not great although it is inevitable. Since the increase in the sheet resistance is related to the shape of the texture, it is possible to reduce the increase in the sheet resistance within 5% by controlling the size (width and height) of the third projections 5 within the range from 0.1 μm to 5 μm by adjusting process conditions on sandblasting, as described above.

TABLE 3

| | Sandblaster etching | ZnO reference |
|---|---|---|
| Sample condition | followed by ZnO coating | (No etching) |
| Sheet resistance (Ω/□) | 54.6 | 45 |

The foregoing descriptions of specific exemplary embodiments of the present invention have been presented with respect to the certain embodiments and drawings. They are not intended to be exhaustive or to limit the invention to the precise forms disclosed, and obviously many modifications and variations are possible for a person having ordinary skill in the art in light of the above teachings.

It is intended therefore that the scope of the invention not be limited to the foregoing embodiments, but be defined by the Claims appended hereto and their equivalents.

What is claimed is:

1. An oxide thin film substrate comprising:
a base substrate having a first texture on a surface thereof; and
a transparent oxide thin film formed on the base substrate, and having a second texture on a surface thereof.

2. The oxide thin film substrate of claim 1, wherein the first texture comprises:
a plurality of first projections formed on the surface of the base substrate, and
a plurality of second projections, at least one second projection from among the plurality of second projections being formed on a surface of each of the plurality of first projections.

3. The oxide thin film substrate of claim 2, wherein a surface roughness (RMS) of the base substrate ranges from 0.1 μm to 20 μm.

4. The oxide thin film substrate of claim 2, wherein a width and a height of the second projection range from 0.1 μm to 1 μm.

5. The oxide thin film substrate of claim 2, wherein the second texture comprises:
a plurality of third projections formed on a surface of the transparent oxide thin film; and
a plurality of fourth projections formed on the entire surface of the transparent oxide thin film, including on surfaces of the plurality of third projections.

6. The oxide thin film substrate of claim 5, wherein each of the plurality of third projections is formed at a position corresponding to the second projection.

7. The oxide thin film substrate of claim 6, wherein a width of the third projections ranges from 0.1 μm to 5 μm, a distance between adjacent third projections from among the plurality of third projections ranges from 0 μm to 10 μm, and a height of the third projections ranges from 0.1 μm to 5 μm.

8. The oxide thin film substrate of claim 7, wherein a width of the fourth projections ranges from 0.01 μm to 0.4 μm, a distance between adjacent fourth projections from among the plurality of fourth projections ranges from 0.01 μm to 0.4 μm, and a height of the fourth projections ranges from 0.01 μm to 0.5 μm.

9. The oxide thin film substrate of claim 1, wherein a haze value of the transparent oxide thin film ranges from 75% to 86%.

10. The oxide thin film substrate of claim 1, wherein a sheet resistance of the transparent oxide thin film ranges from 49Ω/□ to 75Ω/□.

11. A method of manufacturing an oxide thin film substrate, comprising:
forming a first texture on a surface of a base substrate by etching the surface of the base substrate; and
coating the surface of the base substrate on which the first texture is formed with a transparent oxide thin film, thereby forming a second texture on a surface of the transparent oxide thin film.

12. The method of claim 11, wherein forming the first texture on the surface of the base substrate comprises etching the surface of the substrate via sandblaster processing.

13. The method of claim 11, wherein coating the surface of the base substrate with the transparent oxide thin film comprises coating the base substrate with the transparent oxide thin film via atmospheric pressure chemical vapor deposition.

14. A photovoltaic cell comprising the oxide thin film substrate as claimed in claim 1 as a transparent electrode substrate.

15. An organic light-emitting device comprising the oxide thin film substrate as claimed in claim 1 as a light extraction substrate.
